(19) United States
(12) Patent Application Publication
(10) Pub. No.: US 2026/0066021 A1
(43) Pub. Date: Mar. 5, 2026

(54) MULTI-PLANE LEAKAGE DETECTION IN NONVOLATILE MEMORY

(71) Applicant: Sandisk Technologies, Inc., Milpitas, CA (US)

(72) Inventors: Aswani Krishna Lakshiminarayana Addagalla, Bengaluru (IN); V.S.N.K. Chaitanya G, Bengaluru (IN); Pradeep Kumar Anantula, Bengaluru (IN); Sivakumar Grandhi, Bengaluru (IN)

(73) Assignee: Sandisk Technologies, Inc., Milpitas, CA (US)

(21) Appl. No.: 18/825,432

(22) Filed: Sep. 5, 2024

(51) Int. Cl. G11C 29/12

(52) U.S. Cl. CPC G11C 29/12005; G11C 2029/1202

(57) ABSTRACT

An apparatus includes control circuits to connect to planes of a memory array. The control circuits are configured to apply leak-detection voltages to selected blocks, each selected block located in a respective plane of the memory array, obtain a leak-detection indicator for each selected block in parallel and compare each leak-detection indicator with a reference in series.

### BACKGROUND

The present technology relates to nonvolatile memory and operations for detecting defects in nonvolatile memory.

Semiconductor memory is widely used in various electronic devices such as cellular telephones, digital cameras, personal digital assistants, medical electronics, mobile computing devices, non-mobile computing devices and data servers. Semiconductor memory may comprise nonvolatile memory or volatile memory. A nonvolatile memory allows information to be stored and retained even when the nonvolatile memory is not connected to a source of power (e.g., a battery). Examples of nonvolatile memory include flash memory (e.g., NAND-type and NOR-type flash memory), Electrically Erasable Programmable Read-Only Memory (EEPROM), and others. In NAND memory, memory cells are connected in series to form NAND strings.

When a data storage system that includes nonvolatile memory is deployed in or connected to an electronic device (the host), the memory system can be used to store data and read data. For example, data may be stored in response to a program (write) command. Data may be read in response to a read command. Accessing memory cells (e.g., for read, write or erase operations) may include applying appropriate voltages to components of a memory structure. In some cases, defects in nonvolatile memories may result in failure to program and/or read data (e.g., defects may cause leakage currents). In some cases, such failures may affect substantial areas of a memory array. Detecting such defects may avoid impacting memory operation (e.g., avoiding loss of user data).

### BRIEF DESCRIPTION OF THE DRAWINGS

Like-numbered elements refer to common components in the different Figures.

FIG. 1 is a block diagram depicting one embodiment of a storage system.

FIG. 2A is a block diagram of one embodiment of a memory die.

FIG. 2B is a block diagram of an example of an integrated memory assembly.

FIG. 3 shows an example of a portion of a memory structure.

FIGS. 4A-C illustrate an example of a multi-plane memory structure.

FIG. 5 shows an example of a switching circuit.

FIG. 6 shows an example of a driver circuit and leakage detection circuit.

FIG. 7 shows an example of word line leakage currents.

FIG. 8 shows a storage device that includes a leakage detection circuit.

FIG. 9 shows an example implementation of a leakage detection circuit.

FIG. 10 shows an example of an Analog-to-Digital Converter (ADC).

FIG. 11 shows an example of a leakage detection circuit connected to a multi-plane memory structure.

FIG. 12 shows an example of control circuits connected to a multi-plane memory structure to perform leakage detection.

FIG. 13 shows an example of a memory plane with a dedicated current mirror and control circuit.

FIGS. 14A-B illustrate examples of methods of detecting leakage currents in nonvolatile memory structures.

### DETAILED DESCRIPTION

Techniques are disclosed herein to detect current leakage in nonvolatile memory structures. For example, in some cases leakage current between components of a memory structure (e.g., between word lines) may exceed a specified limit. Detecting such leakage (leak-detection) may enable defective portions of a nonvolatile memory array to be identified so that user data is not put at risk (e.g., a defective block may be marked as a bad block in which no user data is stored). Leak-detection operations may require significant time and resources.

Aspects of the present technology are directed to technical problems associated with circuits and methods for efficiently detecting leakage currents in nonvolatile memories. Leakage currents may include one or more of word line-to-word line (WL-WL), word line-to-substrate (WL-SUB), select gate-to-substrate (SG-SUB), word line-to source select gate (WL-SGS), word line-to-drain select (WL-SGD) and/or other leakage currents. Technical solutions may include, in a multi-plane memory structure, providing leak-detection indicator circuits for each plane to enable parallel generation of plane-specific leak-detection indicators. Plane-specific leak-detection indicator circuits may include a current mirror and a current control circuit. Plane-specific circuits may provide plane-specific leak-detection indicators (e.g., analog voltage) to a multiplexer that sends the indicators sequentially to an analysis circuit to determine if leakage current is above a limit for each plane in sequence.

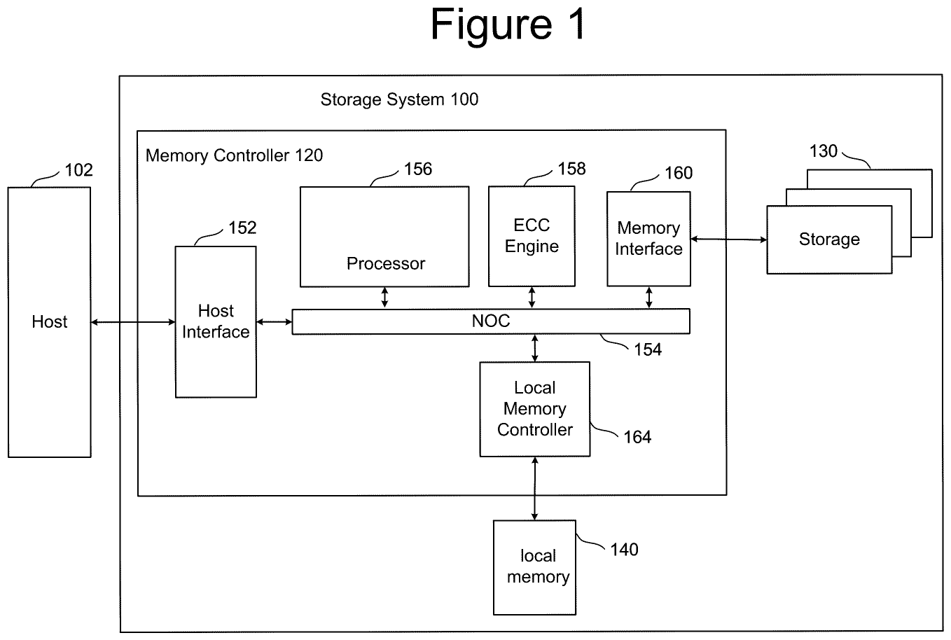

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to nonvolatile storage 130 and local high speed memory 140 (e.g., DRAM, SRAM, MRAM). Local memory 140 is non-transitory memory, which may include volatile memory or nonvolatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the nonvolatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a nonvolatile storage 130 and a subset of the L2P tables are cached (L2P cache) in the local high speed memory 140.

Memory interface 160 communicates with nonvolatile storage 130. In one embodiment, memory interface provides a Toggle Mode interface. Other interfaces can also be used. In some example implementations, memory interface 160 (or another portion of memory controller 120) implements a scheduler and buffer for transmitting data to and receiving data from one or more memory die.

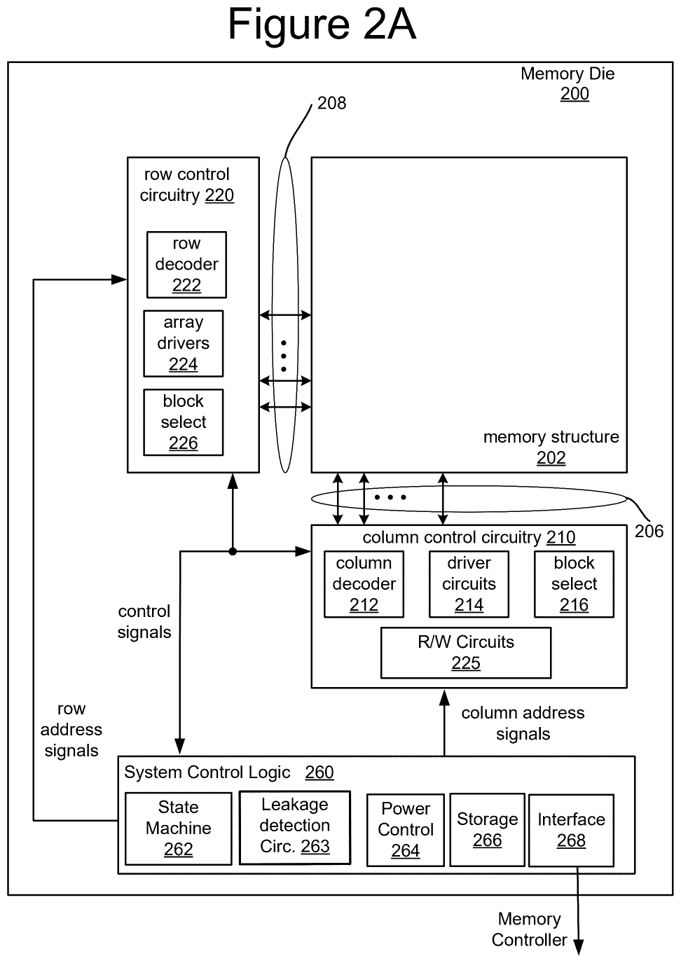

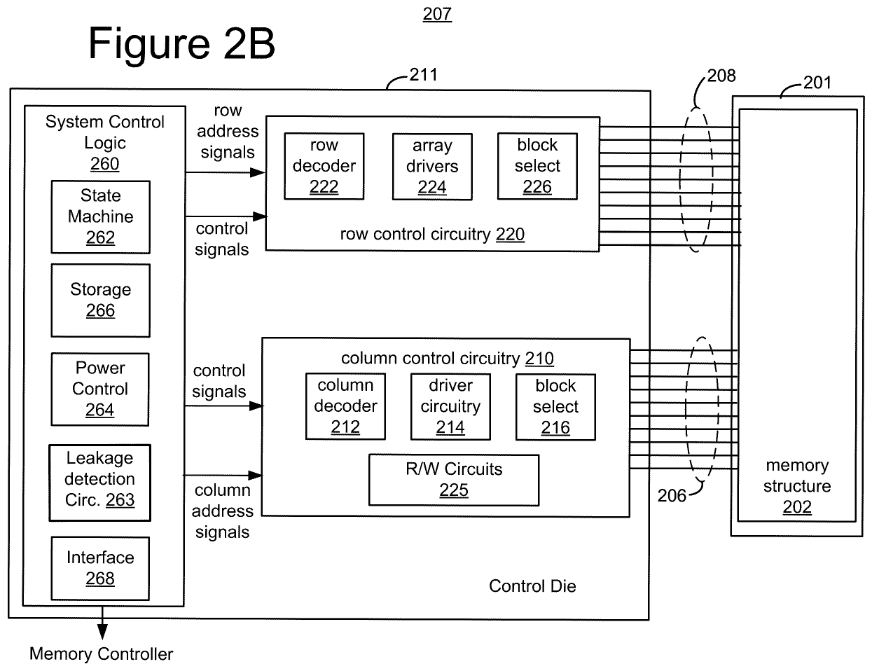

In one embodiment, nonvolatile storage 130 comprises one or more memory dies. FIG. 2A is a functional block diagram of one embodiment of a memory die 200 that comprises nonvolatile storage 130. Each of the one or more memory dies of nonvolatile storage 130 can be implemented as memory die 200 of FIG. 2A. The components depicted in FIG. 2A are electrical circuits. Memory die 200 includes a memory structure 202 (e.g., memory array) that can comprise nonvolatile memory cells (also referred to as nonvolatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202. Leakage detection circuits 263 may detect current leakage in memory structure 202 (e.g., may detect current leakage above a limit between components of memory structure 202 such as between word lines).

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of nonvolatile memory cells in which multiple memory levels are formed above a single substrate, such as a wafer. The memory structure may comprise any type of nonvolatile memory that are monolithically formed in one or more physical levels of memory cells having an active area disposed above a silicon (or other type of) substrate. In one example, the nonvolatile memory cells comprise vertical NAND strings with charge-trapping layers.

In another embodiment, memory structure 202 comprises a two-dimensional memory array of nonvolatile memory cells. In one example, the nonvolatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular nonvolatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

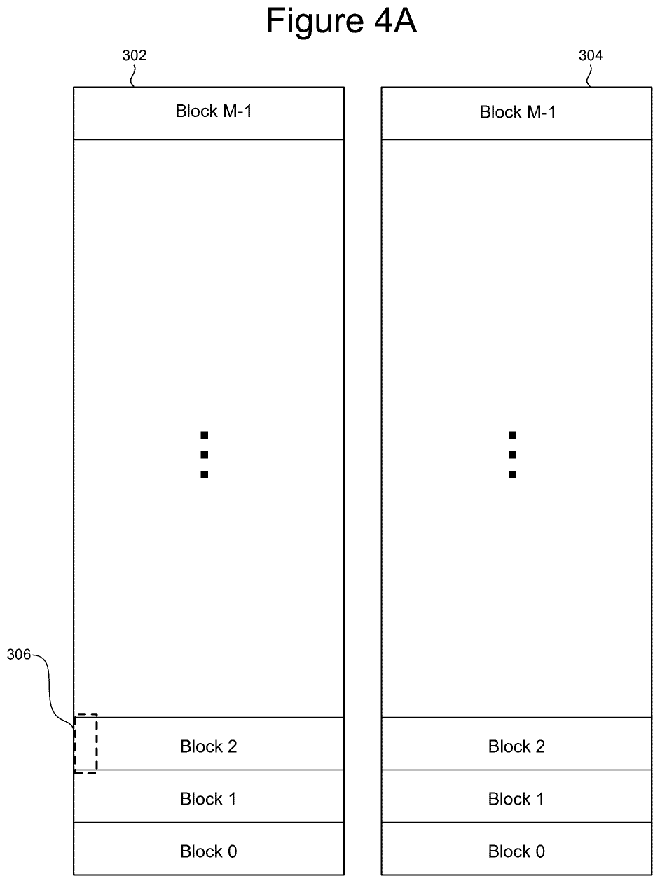

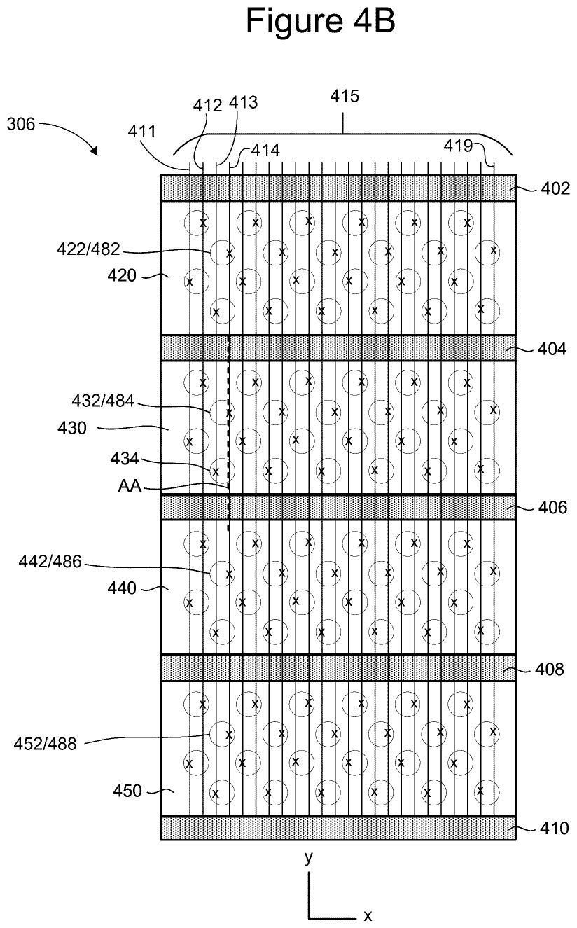

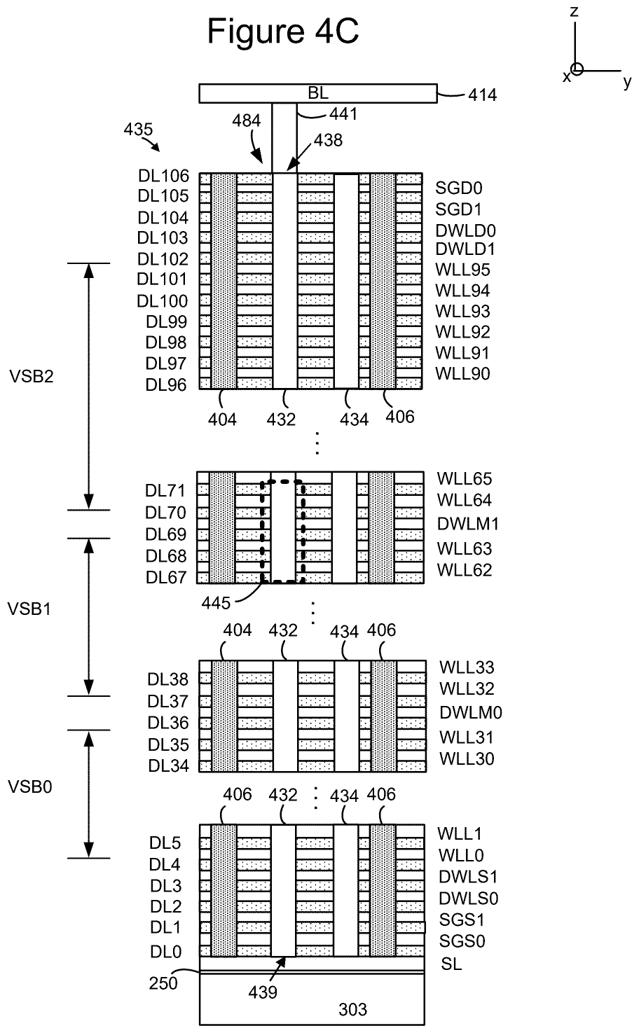

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the nonvolatile storage 130 of storage system 100. The integrated memory assembly 207 includes two types of semiconductor dies (or more succinctly, “die”). Memory structure die 201 includes memory structure 202. Memory structure 202 includes nonvolatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, nonvolatile storage 130, memory die 200, integrated memory assembly 207, and/or control die 211.

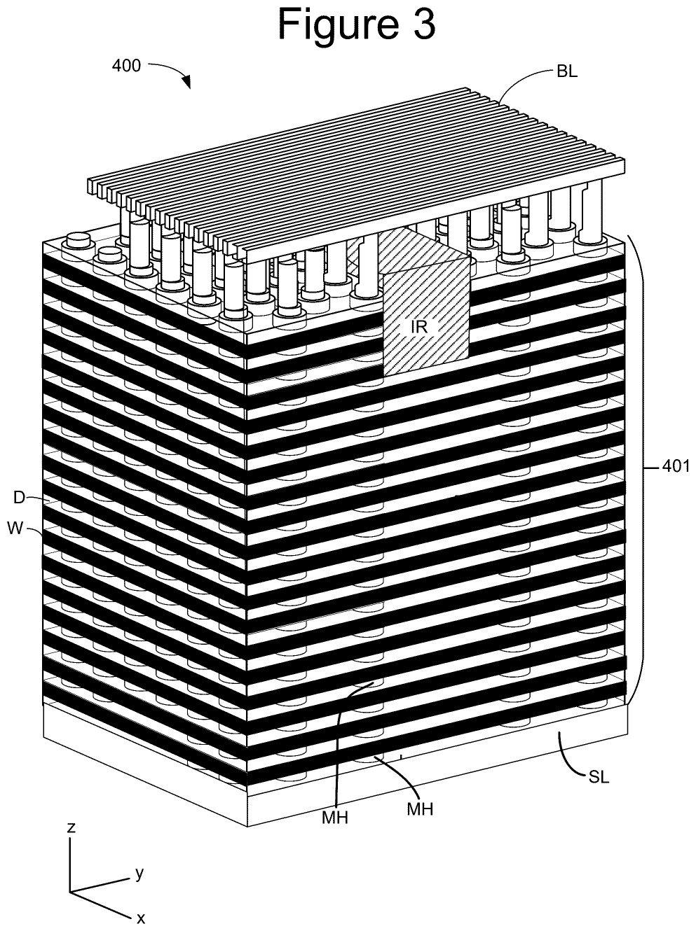

FIG. 3 is a perspective view of a portion of one example embodiment of a monolithic three dimensional memory array/structure that can comprise memory structure 202, which includes a plurality nonvolatile memory cells arranged as vertical NAND strings. For example, FIG. 3 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 3 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

FIG. 4A is a block diagram explaining one example organization of memory structure 202, which is divided into two planes 302 and 304 (multi-plane structure). Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, memory cells can be grouped into blocks for other reasons, such as to organize the memory structure 202 to enable the signaling and selection circuits. In some embodiments, a block represents a groups of connected memory cells as the memory cells of a block share a common set of word lines.

FIGS. 4B-4C depict an example three dimensional (“3D”) NAND structure that corresponds to the structure of FIG. 3 and can be used to implement memory structure 202 of FIG. 2A or 2B. FIG. 4B is a block diagram depicting a top view of a portion of one block from memory structure 202. The portion of the block depicted in FIG. 4B corresponds to portion 306 in block 2 of FIG. 4A. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends beyond the portion shown, the block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy word line layers DWLD0, DWLD1, DWLM1, DWLM0, DWLS0 and DWLS1 are provided, in addition to the data word line layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106.

Vertical columns 432, 434 of memory cells are depicted in the multi-layer stack. The stack includes a substrate 303, an insulating film 250 on the substrate, and a portion of a source line SL. A portion of the bit line 414 is also depicted. Note that NAND string 484 is connected to the bit line 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bit line 414. The local interconnects 404 and 406 from FIG. 4B are also depicted.

The stack 435 is divided into three vertical sub-blocks (VSB0, VSB1, VSB2). Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy word line layer DMLM0 is between vertical sub-block VSB0 and vertical sub-block VSB1. Dummy word line layer DMLM1 is between vertical sub-block VSB1 and vertical sub-block VSB2. The dummy word line layers have dummy memory cell transistors that may be used to electrically isolate a first set of memory cell transistors within the memory string (e.g., corresponding with vertical sub-block VSB0 word lines WLL0-WLL31) from a second set of memory cell transistors within the memory string (e.g., corresponding with the vertical sub-block VSB1 word lines WLL32-WLL63) during a memory operation (e.g., an erase operation or a programming operation).

Leakage currents between components of a memory structure (e.g., memory structure 202) may affect memory operation. For example, insulator (dielectric) material between conductive components (e.g., word lines, bit lines, select lines) may ensure leakage currents are relatively low (e.g. within a specified range or below a specified limit). In some cases (e.g., because of a defect from a die fabrication process) a leakage current may be excessive (e.g., outside a specified range or above a specified limit). Leakage current detection (leak-detection) circuits (e.g., leakage detection circuits 263) may be provided to detect any leakage currents that are outside specified ranges. For example, a block may be tested by applying leakage detection conditions (leak-detection conditions) to the block (e.g., to components including word lines, bit lines, select lines of the block) and checking for any indication of excessive leakage currents. Leakage currents that may be detected in this way may include word line-to-word line (WL-WL), word line-to-substrate (WL-SUB), select gate-to-substrate (SG-SUB), word line-to source select gate (WL-SGS), word line-to-drain select (WL-SGD) and/or other leakage currents. While examples of leakage detection in this document may be described with respect to specific components (e.g., WL-WL leakage) the present technology is not limited to detecting leakage between any specific components and the examples of the present document are for illustration purposes and are not intended to be limiting.

There is an ongoing effort to reduce memory devices to ever smaller scales, which may affect leakage currents. As the technology scales down to 20 nm and 10 nm memory cells, for example, the distance between the word lines are consequently 20 nm or 10 nm. Tolerances become more important and the structure/device is more prone to defects that can cause word lines to leak current to the substrate or to adjacent word lines. Current leakage correlates with dies that fail cycling due to grown defects and, in some cases, detectable leakage may precede actual program status failure so that leakage current detection may be used to avoid certain problems (e.g., detection of leakage currents may allow a bad block to be detected before it fails so that user data is not lost).

Aspects of the present technology enable word line leakage tests to be performed automatically and internally to a nonvolatile memory system in a way that can be done with various voltage biases and multiple stress topologies. The claimed solutions can be done during testing (e.g., in a manufacturing and test facility) and/or in the field after a chip is packaged and may allow a system to detect different leakage levels.

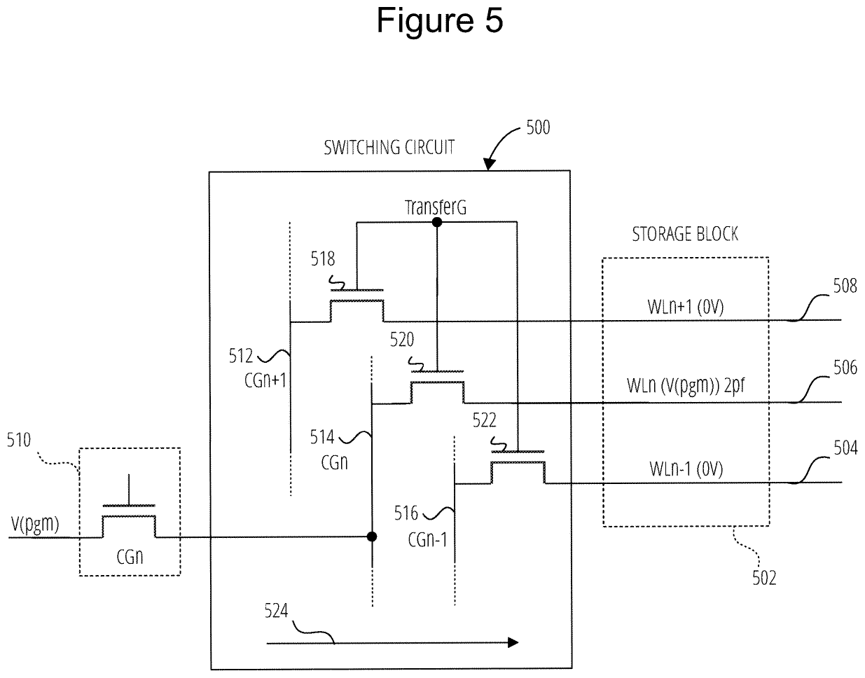

FIG. 5 illustrates a storage block 502 (block) of memory structure 202 connected to switching circuit 500. The planes of a memory circuit can have on the order of several thousand storage blocks, one of which is shown as storage block 502 and each storage block may have several dozen word lines, three of which are explicitly shown as WLn−1 504, WLn 506, and WLn+1 508. A high voltage may be applied on the selected word lines, such as WLn 506 during program and read operations. “Selected word line” refers to a word line designated for use in a particular storage operation or memory operation. Certain storage operations such as programming, reading, or sensing, may be performed on memory cells of a selected word line through a series of one or more steps. Other storage operations such as erasing memory cells, in one embodiment, may be performed on memory cells of a plurality of word lines (e.g., all word lines of a block such as block 502) simultaneously through a series of one or more steps.

In the example of FIG. 5, a program voltage (VPGM) is generated by a pump and supplied to the first decoding CGN block 510, represented here as a switch. CGN block 510 is a storage block to supply the various kinds of voltages (e.g., 3 to 5 volts) according to the mode of operations for each global control gate (CG) control lines (also referred to as global word lines). Three of the CG lines (CGn+1 512, CGn 514, CGn−1 516) are shown explicitly, corresponding to the illustrated word lines. The CG lines (as many as the number of word lines in each storage block) will route to the row (storage block) decoder of the memory array. In addition to block 502, the CG lines run to the other storage blocks of the plane of block 502, so that these CG lines may route with the top metal layer and run through the row decoders of the planes (not illustrated).

The switching circuit 500 is configured to deliver a high voltage such as VPGM to a combination of word lines of a storage block. For example, the switching circuit 500 may enable a single word line to receive VPGM or a combination of word lines to receive VPGM, such even numbered word lines and/or odd numbered word lines.

In one embodiment, each storage block is decoded with a local pump. When the storage block is selected, a logic signal enables the local pump to apply a high passing voltage transferG on the gates of a combination of passing transistors (here represented by passing transistor 518, passing transistor 520, and passing transistor 522 for the three illustrated word lines) in the row decoder. Logic may control the gates of the passing transistors such that the high voltage VPGM is coupled to the selected word lines, such as even selected word lines (WLn−1 504 and WLn+1 508).

The high voltage, VPGM, on the corresponding global CG, CGN block 510, is transferred to the word line(s) of the selected storage block. Here, by way of example, WLn−1 504 and WLn+1 508 are coupled to VPGM, with WLn 506 taken to ground (or more generally a low voltage level), corresponding to a word line to word line leakage test pattern (leak-detection conditions) that checks for leakage current through even selected word lines.

During one or more different word line leakage tests, the word lines can have different bias topology according to the defects to be detected. When detecting word line to substrate short, all the word lines may be biased to high voltage of a same level, with the substrate coupled/biased to ground. When detecting word line to neighbor word line shorts, the word lines in the storage block may be biased alternatively at high voltage (VPGM) and 0 volts, as shown in FIG. 5. Different leak-detection conditions (leak-detection voltages) may be applied according to the components being tested for current leakage.

Switching circuit 500 facilitates applying leak-detection conditions by coupling of selected word lines to a suitable voltage (e.g., VPGM) or voltages for leakage current testing. Switching circuit 500 may be used as described above to direct/couple/supply a reference voltage and/or reference current to a leak-detection circuit as part of a leakage current test and to direct a reference voltage and/or reference current to a particular set of word lines, such as those shown in storage block 502 as part of a leakage current test. “Reference voltage” refers to a voltage configured to serve as a reference when conducting one or more tests of an electronic circuit. In one embodiment, a reference voltage may be used to provide voltage to test circuitry such as a leakage detection circuit. In certain embodiments, a reference voltage may be configured to have a magnitude designed for a test performed using the test circuitry. In an embodiment, an existing voltage for an electronic device may be re-purposed for use in providing voltage to test circuitry such as a leakage detection circuit. For example, in one embodiment, the leakage detection circuit may be couplable to word lines of a nonvolatile memory array and the reference voltage may comprise a programming voltage, identified as VPGM.

In certain embodiments, the test for leakage current may detect very low leakage current (e.g., as low as 25 nanoAmps or less). Some embodiments may include first determining a reference code (digital, multi-bit code) and then using the reference code to evaluate a leakage code (digital, multi-bit code). In an example, the CGN block 510 may be used to supply a reference voltage (e.g., Vpgm) to the switching circuit 500 in order to determine a reference code (digitized reference voltage) and also to the selected word lines in order to determine a leakage code (digitized leakage voltage).

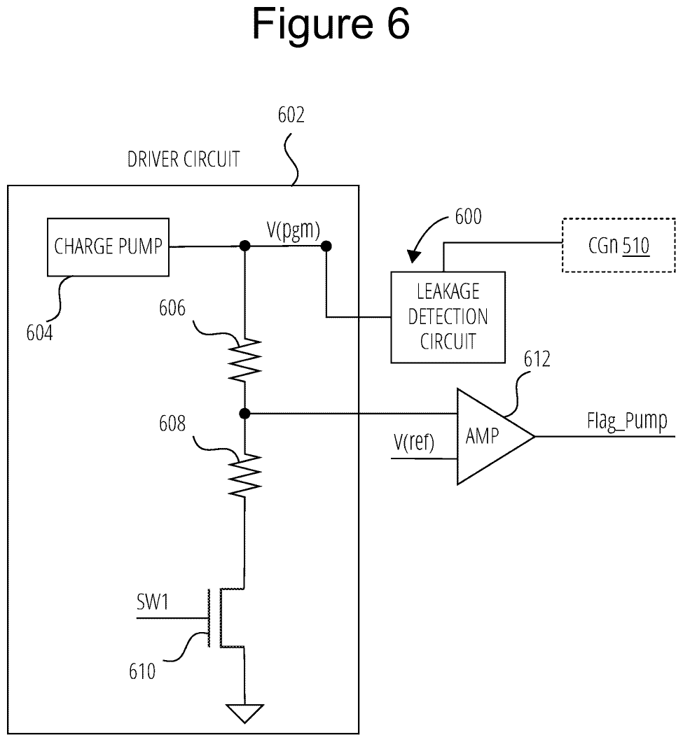

FIG. 6 illustrates a driver circuit 602 that includes a charge pump 604 coupled to a leakage detection circuit 600 (e.g., leakage detection circuit 263). A high voltage charge pump 604 may be regulated by a resistor divider, such as shown in FIG. 6. The high voltage Vpgm is divided by the resistor 606 and resistor 608, connected to ground (or more generally the low voltage level) through the switch 610, and the compare point voltage for the amp 612 will be voltage reference vref (e.g., 1.2 volts). The resistor divider formed by resistors 606 and 608 may have a leakage current of about 10 μA. The differential amplifier or comparator (amp 612) may be used to output a digital voltage, flag-pump, which may control a pump clock. When the charge pump 604 is pumped to the target level, the flag_pump bit will be low to turn off the pump clock. When the high voltage drops below certain level, the flag pump signal will go high to enable the pump clock and turn on the pump to supply high voltage.

Driver circuit 602 may supply a word line voltage, and/or a reference voltage, such as V(pgm) to leakage detection circuit 600 and to a set of word lines to detect leakage current from the set of word lines. “Leakage detection circuit” (or “leak-detection circuit”) may refer to a circuit, sub-circuit, circuitry, electronic component, hardware, software, firmware, module, logic, device, or apparatus configured, programmed, designed, arranged, or engineered to sense/detect/determine current leakage current within, or from, one or more target control lines that are tested or checked for leakage current. In one embodiment, the target control lines may comprise one or more of word lines, bit lines, NAND strings, memory cells, and the like of a memory structure (e.g., memory structure 202).

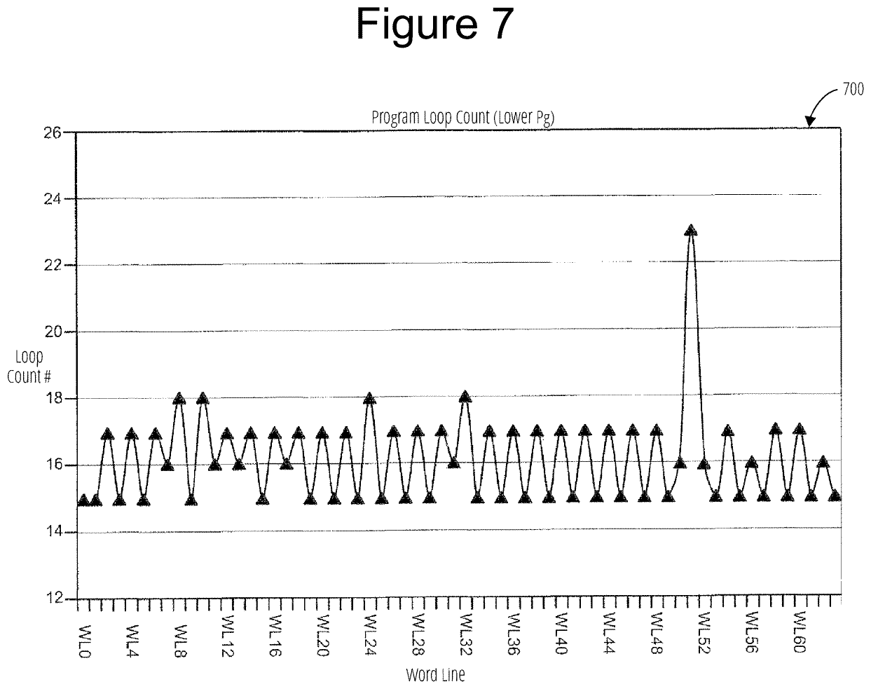

FIG. 7 illustrates a graph indicating leakage current in word lines 700. Programming a broken word line may show some program loop variation, but word line-to-word line and storage block-to-storage block variation may make it difficult to judge the failure based on the program loop count. FIG. 7 shows the number of pulse-verify, iterations, or loop count, for each word line to program, in this example, lower page into a 64 word line storage block. The loop count fluctuates over the different word lines by several counts. In the case of WL50, the loop count is noticeably higher than the other fluctuations, which may indicate a broken, or shorted, word line.

Memory devices may be configured to perform a scan to check for failed memory bits when programming. Examples of the present technology may incorporate word line leakage detection into such a routine (e.g., performed at intervals during use by a consumer, in addition to factory testing prior to use by a consumer). The disclosed embodiments allow a broken/leaking word line check to be performed many times after the device has been in operation, exemplary embodiments may detect breakages that manifest themselves after device test, use by a customer, or that are not detectable at every test.

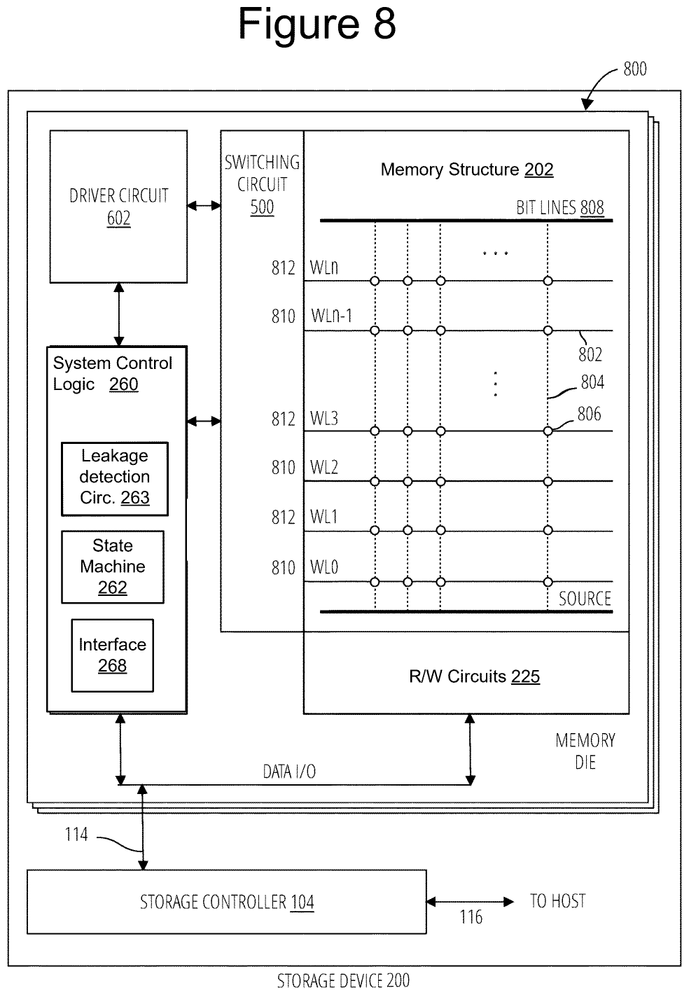

FIG. 8 illustrates a memory die 800 that may be used to implement aspects of the present technology. The memory die 800 includes system control logic 260 incorporating leakage detection circuits 263, a state machine 262 and interface circuits 268. System control logic 260 is connected to read/write circuits 225 (R/W Circuits) and nonvolatile memory structure 202. The memory die 800 also includes driver circuit 602 (e.g., as illustrated in FIG. 6). The driver circuit 602 and system control logic 260 (including leakage detection circuit 263) are connected to memory structure 202 through switching circuit 500 (e.g., as illustrated in FIG. 5), which may allow appropriate leak-detection conditions (leak-detection voltages) to be applied to components of memory structure 202 (e.g., to one or more selected control line of a selected block).

Memory structure 202 includes word lines (e.g., exemplary word line WLn−1 802) coupled to NAND strings 804 running between a source line and bit lines 808. The memory cells 806 are formed along the NAND strings 804 and are positioned where the NAND strings 804 intersects the word lines.

Word lines are numbered consecutively WL0 to WLn starting from the source line to the bit lines. The word lines may be grouped and selected for leakage current detection, using a pattern of even selected word lines 810 and odd selected word lines 812 in one embodiment. In other words, a leakage current detection test may be performed separately on even selected word lines 810 and on odd selected word lines 812.

The driver circuit 602 may supply a word line voltage to a set of the word lines 802 to detect leakage current, which may be represented by a leakage code, from those word lines 802. The driver circuit 602 may also supply a word line voltage, such as a reference voltage to a leakage detection circuit 263 as part of a leakage current detection test in which the leakage detection circuit 600 determines a reference code.

In one embodiment, the memory structure 202 of the memory die 800 may comprise one or more planes, each comprising a plurality of storage blocks. Control circuits (e.g., system control logic 260) may iteratively test a set of even selected word lines 810 and odd selected word lines 812 within each storage block to detect leakage current among the even selected word lines and odd selected word lines in turn. The word line voltage from the driver circuit 602 may be selectively coupled to particular sets of word lines through the switching circuit 500.

System control logic 260 may direct the leakage detection circuits 263 to conduct one or more leakage current tests. In certain embodiments, system control logic 260 may use the leakage detection circuits 263 to determine a reference code (e.g., a digital reference or digital code that includes multiple bits) and then use that reference code in evaluating a leakage code.

System control logic 260 may compare the reference code and the leakage code provided by the leakage detection circuits 263. If the leakage code exceeds the reference code, the system control logic 260 may determine that the set of word lines tested has unacceptable leakage current. In one embodiment, the system control logic 260 may employ the leakage detection circuits 263 to perform leakage current detection on a subset of the set of word lines such that specific word lines with a fault that is causing the unacceptable leakage current is identified.

Memory structure 202 may comprise two or more planes (e.g., as shown in FIG. 4A). Each plane may be organized into a plurality of physical blocks. Each physical block may comprise word lines 802 having memory cells 806 coupled to NAND strings 804 coupled to bit lines 808.

System control logic 260 of this embodiment may direct the leakage detection circuits 263 to determine a reference code corresponding to a leakage current threshold. System control logic 260 may direct the leakage detection circuits 263 to determine an even leakage code that comprises leakage current from even selected word lines 810. “Even leakage code” refers to a leakage code configured to reference a level of leakage current from evenly numbered word lines in a nonvolatile memory array (either within a single plane or across multiple planes of a memory die). System control logic 260 may then compare the reference code and the even leakage code and determine that the even selected word lines 810 have unacceptable leakage current if the even leakage code exceeds the reference code.

Similarly, system control logic 260 may direct the leakage detection circuits 263 to determine an odd leakage code comprising leakage current from odd selected word lines 812. System control logic 260 may compare the reference code and odd leakage code, and, if the odd leakage code exceeds the reference code, system control logic 260 may determine that the odd selected word lines 812 have unacceptable leakage current. “Odd leakage code” refers to refers to a leakage code configured to reference a level of leakage current from oddly numbered word lines in a nonvolatile memory array (either within a single plane or across multiple planes of a memory die).

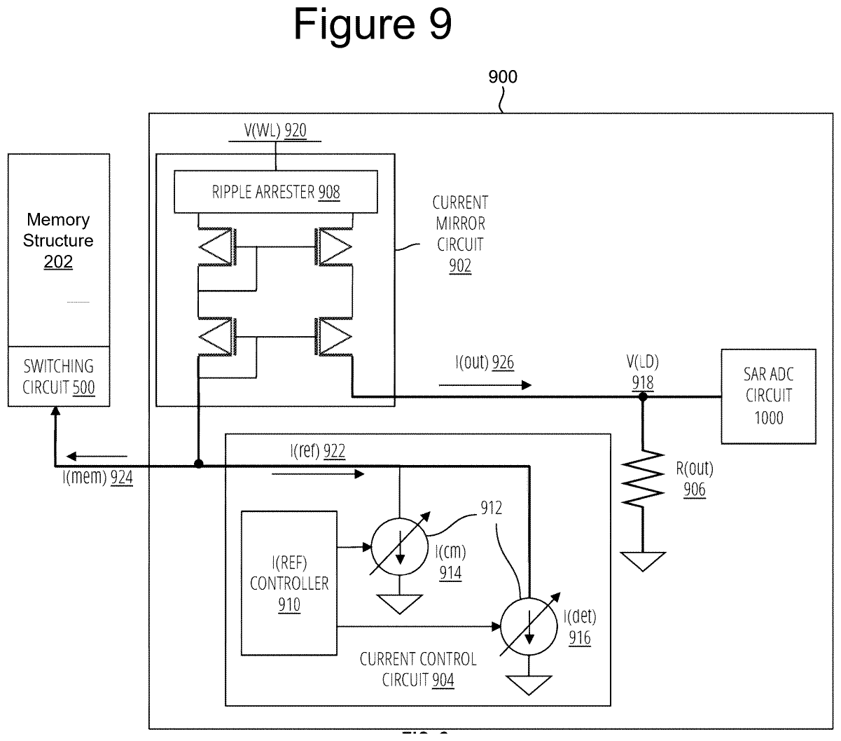

FIG. 9 illustrates a leakage detection circuit 900 (e.g., used as at least a part of leakage detection circuits 263). The leakage detection circuit 900 comprises a current mirror circuit 902, a current control circuit 904, a resistor 906, and a SAR ADC circuit 1000. The current mirror circuit 902 may include a ripple arrester 908. The current control circuit 904 may comprise a reference current controller 910 (I(ref) controller) and variable current sources 912, including a common mode current 914 (I(cm) current source) and a detection current 916 (I(def) current source).

The current control circuit 904 together with logic, the switching circuit 500, and certain other switches manages the leakage detection circuit 900 to obtain a reference code and a leakage code. A current level for each of one or more variable current sources (e.g., variable current sources 912) may be selected by current control circuit 904. The current control circuit 904 uses variable current sources 912 to manage and configure the testing for leakage current.

The current control circuit 904 may supply the reference current I(ref) 922 used to determine the leakage current threshold in order to detect leakage current within the set of word lines of memory structure 202 selected by the switching circuit 500. In order to generate the reference current 922, the current control circuit 904 may include a reference current controller 910 configured to control variable current sources 912. The variable current sources 912 may be set, or configured, to draw a current consistent with normal operation of the memory die design, in the form of detection current 916. In some embodiments, the variable current sources 912 may also be configured to draw a common mode current 914 in order to maintain the operation of the current mirror circuit 902. “Common mode current” refers to a current that flows in the same direction as another current in a control line.

The current mirror circuit 902 may be coupled to a word line voltage 920 provided by a driver circuit and may be coupled to the current control circuit 904. The current mirror circuit 902 may at any given time mirror the reference current 922 supplied by the current control circuit 904 or the memory current 924 from a set of word lines of the memory structure 202, as selected, at least in part, by the switching circuit 500. For example, a first (left) branch of current mirror circuit 902 is connected to switching circuit 500 and reference current controller 910 so that I(mem) or I(ref) may flow through this branch and may be mirrored by the second (right) branch (e.g., I(out) may mirror I(mem) or I(ref)).

In mirroring these currents, the current mirror circuit 902 may produce an output current 926 reflecting, and/or representative of, the mirrored current. The current mirror circuit 902 may in some embodiments comprise a ripple arrester 908 configured to mitigate voltage spikes from the driver circuit.

The current mirror circuit 902 and resistor 906 connect in series to the SAR ADC circuit 1000. The SAR ADC circuit 1000 generates one of the reference code and the leakage code. “Successive approximation analog to digital conversion circuit” or “SAR ADC circuit” may refer to a type of analog-to-digital converter that converts analog values into discrete digital representations via search through possible quantization levels (range of values) before finally converging upon a digital output for each conversion.

The resistor 906 is configured such that at a given time a current corresponding to one of the reference current 922 or the memory current 924 may flow through resistor 906 (depending on which phase/stage of a leakage detection test being performed) to generate a leakage detection voltage V(LD) at node 918. The resistor 906 may connect between the current mirror circuit 902 and the SAR ADC circuit 1000. The resistor 906 may be configured to transform the output current I(out) 926 (mirroring either the reference current 922 or the memory current 924) into a leak-detection voltage V(LD). In one embodiment, the resistor may be a 200 kΩ resistor.

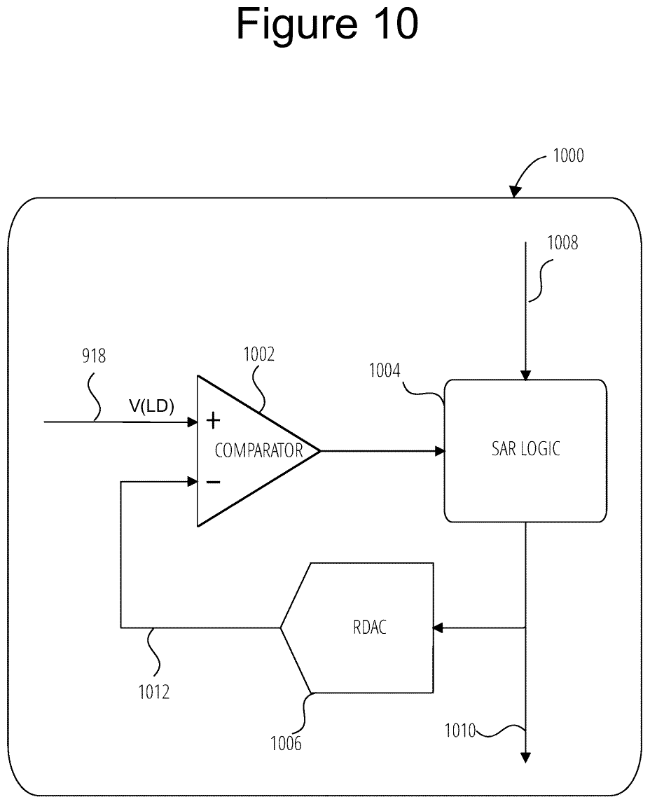

The SAR ADC circuit 1000 may receive the leak-detection voltage V(LD) at node 918 and may generate a digital output code based on the leak-detection voltage V(LD). The digital output code may comprise a reference code when the leak-detection voltage V(LD) reflects the reference current 922 or may comprise a leakage code when the leak-detection voltage V(LD) reflects the memory current 924. The driver circuit previously described may supply the word line voltage 920 to the set of word lines of the memory structure 202 when the leakage detection circuit 900 determines either the reference code or the leakage code. Operation of the SAR ADC circuit 1000 is described in greater detail with respect to FIG. 10.

The switching circuit 500 of the memory die may connect to the current mirror circuit 902. The switching circuit 500 may be connectable to the set of word lines of the memory structure 202 and the memory current 924 in response to a signal from system control logic 260. The switching circuit 500 may, in some embodiments, also connect to the current control circuit 904 and the reference current 922. The switching circuit 500 together with the current control circuit 904 enables connecting and disconnecting sets of word lines to the current mirror circuit 902 such that a reference code may be generated and alternately a leakage code may be generated.

During leakage testing, in accordance with one embodiment of this disclosure, the current mirror circuit 902 of the leakage detection circuit 900 may be configured to generate an output current 926 by mirroring the reference current 922 drawn by the current control circuit 904. This reference current 922 may be generated through manipulation of the variable current sources 912 by the reference current controller 910. The reference current controller 910 may set one variable current source to draw a common mode current 914 to support and reflect basic operation of the current mirror circuit 902. The reference current controller 910 may also set one variable current source to draw a detection current 916 based on the acceptable operation of the portions of the memory structure 202 to be tested (i.e., the sets of word lines forming storage blocks, physical erase blocks, etc.). With these variable current sources 912 set as desired, the current mirror circuit 902 may generate an output current 926 equal to or proportional to the reference current 922.

The output current 926 representing the reference current 922 may be used to generate a reference leak-detection voltage at node 918. The SAR ADC circuit 1000 may accept this reference leak-detection voltage as input and may generate a digitalized reference code reflective of the reference leak-detection voltage. This digitalized reference code generated by the SAR ADC circuit 1000 may be a multi-bit digital output code (e.g., nine bits). The reference code may be stored for further use in, for example, a dedicated register, or in some other accessible location. In some embodiments, a combination of circuitry in the switching circuit 500 and the current control circuit 904 may disconnect the leakage detection circuit 900 from the set of word lines of a storage block of the memory structure 202 before the reference current 922 is connected to the current mirror circuit 902. In this manner, a reference code may be determined without influence from word lines in a storage block of the memory structure 202.

The switching circuit 500 may be configured to connect the current mirror circuit 902 input side to the set of word lines to be tested. The word line voltage 920 may be applied to the set of word lines through the action of the current mirror circuit 902 and the switching circuit 500, which may cause the word lines under test to draw a memory current 924. The current mirror circuit 902 may reflect an output current 926 equal or proportional to this memory current 924.

The output current 926 reflective of the memory current 924 may be used to generate a leak-detection voltage V(LD) at node 918. These leak-detection voltages may be digitalized by the SAR ADC circuit 1000 into leakage codes, similar to the development of the reference code, and as described in greater detail below. This leakage code may be a multi-bit digital output code.

Once a reference code and a leakage code have been determined for a set of word lines under test, these two codes may be compared. If the leakage code is less than or equal to the reference code, this indicates that the set of word lines under test is drawing current commensurate with normal operation, and no word lines have an unacceptable level of leakage current. If the leakage code exceeds the reference code, this may indicate an unacceptable level of leakage current within the set of word lines. In some embodiments, a predetermined leakage current threshold may be reflected, captured, or represented by the reference code.

When a set of word lines exhibits leakage current in excess of a leakage current threshold, as indicated by examination of the leakage code, the storage block containing those word lines may be deemed a bad block and may be marked as unusable. This testing may be repeated for multiple sets of word lines within a storage block, and for all storage blocks within a memory die.

FIG. 10 illustrates an example of SAR ADC circuit 1000. The SAR ADC circuit 1000 comprises a comparator 1002, a successive approximation logic circuit 1004, and a resistor digital to analog converter circuit 1006. The comparator 1002 takes as one input the leak-detection voltage V(LD) at node 918 generated within the leakage detection circuit 900 as described above. The successive approximation logic circuit 1004 takes in the output of the comparator 1002, as well as an input clock 1008. The successive approximation logic circuit 1004 may be configured to output one bit of a digital output code 1010 on each clock cycle of the input clock 1008, starting with a most significant bit (MSB). In an example, successive approximation logic circuit 1004 performs a binary search to successively approximate a digital code that represents the leak-detection voltage (e.g., comparator 1002 may compare V(LD) with references selected from a range of references by SAR logic circuit 1004 using a binary search algorithm). Digital logic (e.g., in SAR ADC circuit 100 or in system control logic 260) may compare the digital codes (digitized leak-detection voltages) with the reference code to determine if leakage current is less than a limit.

This digital output code 1010 may be converted back into analog form by the resistor digital to analog converter circuit 1006. The resistor digital to analog converter circuit 1006 may be configured to convert each successive bit of the digital output code 1010 into an analog feedback signal 1012 and may provide the analog feedback signal 1012 to the comparator 1002.

“Successive bit” may refer to a next bit in a binary encoding that progressively evaluates each bit in a binary code in a predefined order. In one embodiment, each bit of a binary encoding is evaluated starting with a most significant bit, then a next most significant bit, in sequence until a least significant bit is evaluated. The comparator 1002 may be configured to receive the leak-detection voltage V(LD) and the analog feedback signal 1012, and to send a signal to the successive approximation logic circuit 1004 in response to the analog feedback signal 1012 exceeding the leak-detection voltage V(LD).

In one embodiment, the SAR ADC circuit 1000 may detect a change in leak-detection voltage V(LD) at node 918 of about 4.6 mV, corresponding to a change in the memory current of about 24 nA-25 nA. The SAR ADC circuit may be configured to determine one bit of a digital output code on each clock cycle and operate at a clock speed such that the SAR ADC circuit converts the leak-detection voltage to a nine-bit digital output code in less than 5 microseconds. In one embodiment, the input clock speed may be 4.2 MHz.

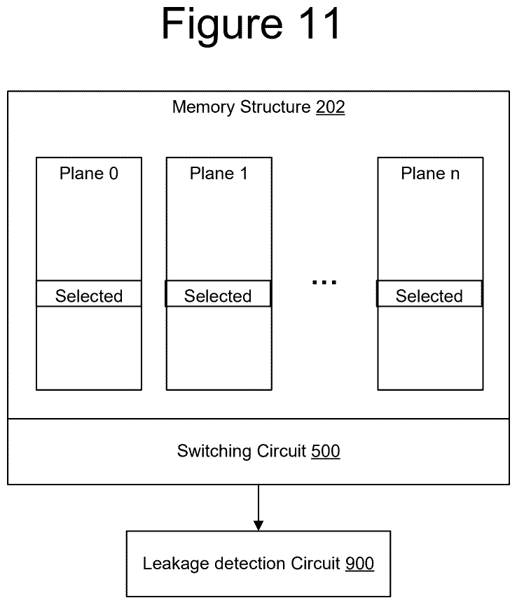

FIG. 11 shows an example of a leak-detection operation using leakage detection circuit 900 to detect current leakage in a multi-plane memory structure 202. In this example, memory structure 202 includes n planes (e.g., n may be two, four, eight, or more). One block is selected in each plane (e.g., switching circuit 500 may connect current control circuit 904 to the selected blocks to provide I(mem) to the selected word lines of the selected blocks. Current mirror circuit 902 provides I(out) 926, which causes voltage V(LD) to be input to SAR ADC 1000. The value of I(out) or corresponding value of V(LD) may be used as a collective leak-detection indicator for the selected blocks so that comparing a corresponding digital output code with a reference code may indicate if leakage is below a limit. If the value of I(out) or V(LD) is acceptable, as indicated by a digital output code less than the reference code, then selected blocks of all n planes may pass leak testing. However, if the value of I(out) or V(LD) is not acceptable, as indicated by a digital output code that is greater than the reference code, then selected blocks of n planes are checked individually to identify if any individual selected block generates an unacceptable value. Checking n blocks sequentially in this manner may be time consuming.

In some cases, using a collective leak-detection indicator may result in a significant number of false positive detections (e.g., a collective leak-detection indicator may exceed an acceptable range even though no individual block exceeds an acceptable range). For example, where acceptable range of I(out) is less than 2 uA and n=4 (four planes), if each selected block generates a leakage current of 1 uA, the total leakage current is 4 uA, which indicates unacceptable leakage and may trigger plane-by-plane leak checking, which shows selected blocks of all planes have leakage currents below 2 uA. Sequential testing in response to such false-positive indicators may consume significant time.

According to some aspects of the present technology, control circuits are provided to enable leak-detection indicators for selected blocks of multiple planes to be generated in parallel. In contrast with the collective leak-detection indicator discussed above, circuits may output individual leak-detection indicators for each selected block (e.g., in an n-plane arrangement, n leak-detection indicators may be generated in parallel for the n selected blocks)

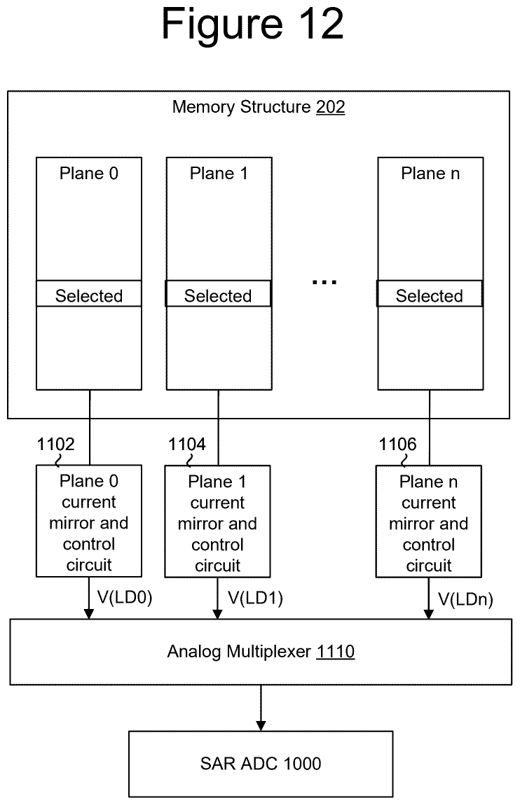

FIG. 12 shows an example of control circuits that include individual plane-specific current mirror and control circuits for each plane (e.g., Plane 0 current mirror and control circuit 1102, Plane 1 current mirror and control circuit 1104, . . . Plane n current mirror and control circuit 1106) to generate respective leak-detection indicators for each plane (e.g., for planes 0 to n). Leak-detection indicators (e.g., leak-detection voltages V(LD0), V(LD1), . . . V(LDn)) may correspond to leakage currents in selected blocks of corresponding planes and are provided as inputs to analog multiplexer 1110 (analog MUX). Analog multiplexer 1110 may select one leak-detection indicator (selected leak-detection voltage) at any time and provide the selected leak-detection indicator (leak-detection voltage) as an output to SAR ADC 1000, which may convert the leak-detection indicator to a digital code. This code is compared with a reference code to determine if the selected block of the corresponding plane exceeds the leakage current limit. Control circuits of FIG. 12 (e.g., current mirror and control circuits 1102, 1104, 1106, analog multiplexer 1110 and SAR ADC 1000) may be considered an example of means for applying leak-detection voltages to selected blocks, each selected block located in a respective plane of the plurality of planes to obtain a leak-detection indicator for each selected block in parallel and comparing each leak-detection indicator with one or more reference in series.

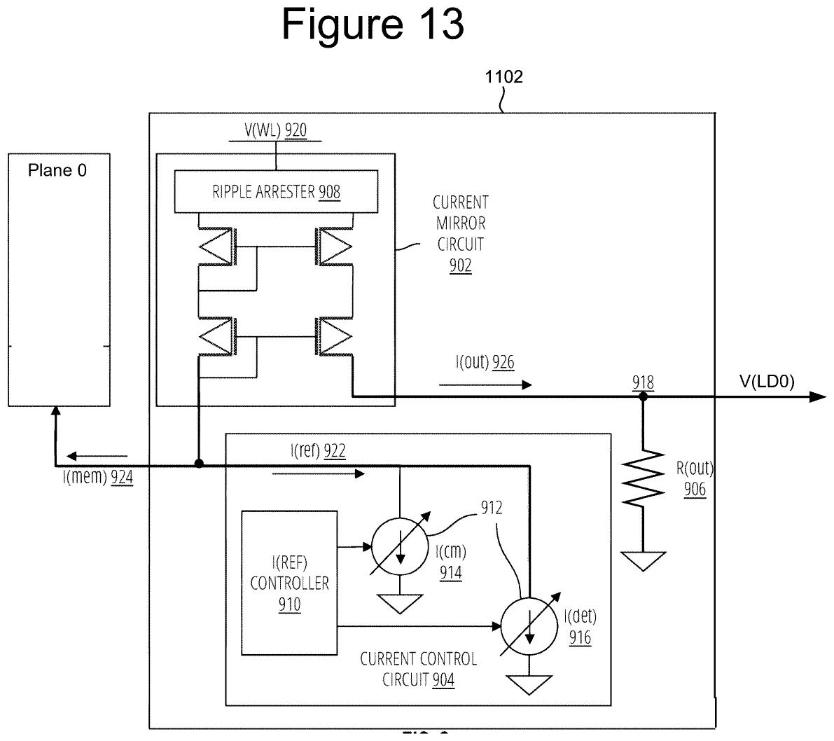

FIG. 13 shows an example implementation of Plane 0 current mirror and control circuit 1102, which is connected to plane 0 (each current mirror and control circuit including Plane 1 current mirror and control circuit 1104 to Plane n current mirror and control circuit 1106 may be identical to Plane 0 current mirror and control circuit 1102). Plane 0 current mirror and control circuit 1102 (leak-detection indicator circuit) includes current mirror circuit 902 and current control circuit 904, which were previously described with respect to leakage detection circuit 900. Unlike leakage detection circuit 900, Plane 0 current mirror and control circuit 1102 does not include SAR ADC circuit 1000. In this example, while each plane has respective dedicated plane-specific current mirror and control circuits (leak-detection indicator circuits) to generate respective plane-specific leak-detection indicators (respective leak-detection voltages in the example illustrated), a common SAR ADC circuit 1000 is shared through Analog Multiplexer 1110 so that node 918 is the output terminal (output node) of Plane 0 current mirror and control circuit 1102.

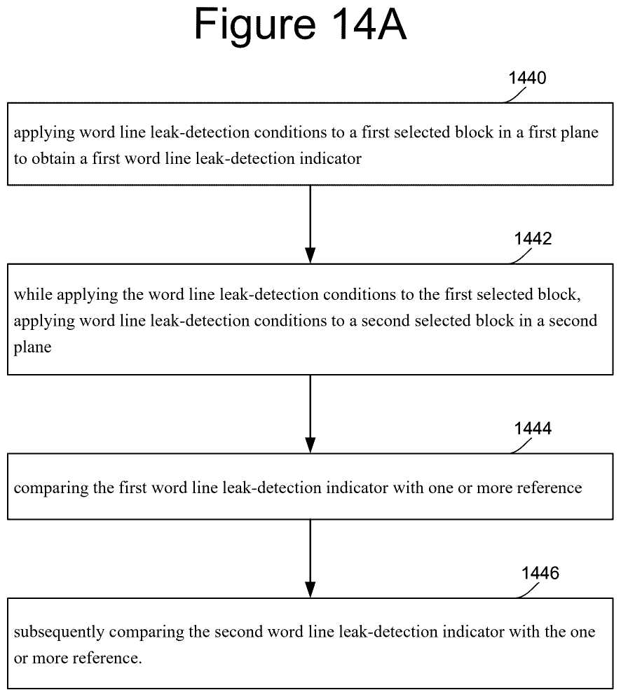

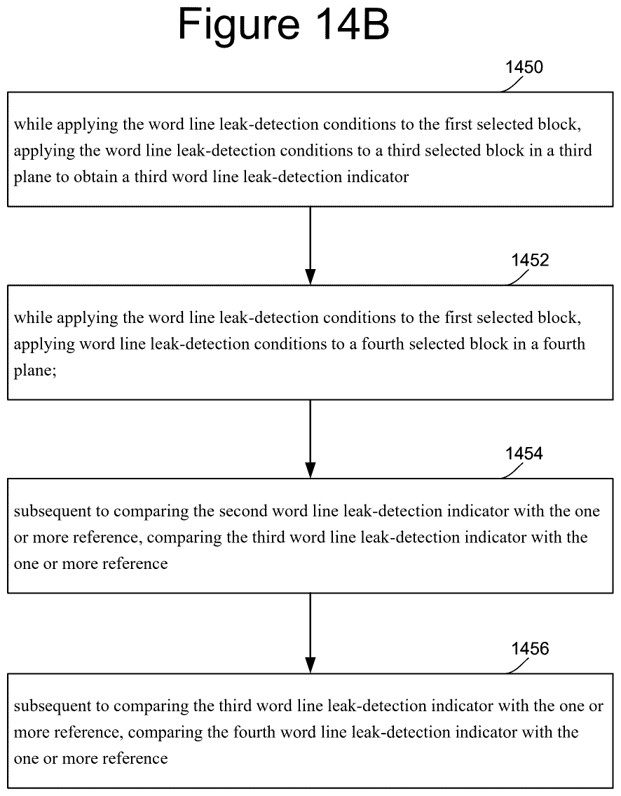

FIG. 14A shows an example of a method that illustrates aspects of the present technology and may be implemented using circuits described above (e.g., in FIGS. 12-13). The method includes applying word line leak-detection conditions to a first selected block in a first plane to obtain a first word line leak-detection indicator 1440 and while applying the word line leak-detection conditions to the first selected block, applying word line leak-detection conditions to a second selected block in a second plane 1442 (e.g., Plane 1 current mirror and control circuit 1104 applying word line leak-detection conditions to a selected block in plane 1 while Plane 0 current mirror and control circuit 1102 applies the word line leak-detection conditions to a selected block in plane 0). The method also includes comparing the first word line leak-detection indicator with one or more reference 1444 and subsequently comparing the second word line leak-detection indicator with the one or more reference 1446 (e.g., SAR ADC 1000 comparing V(LD0) with a reference and subsequently comparing V(LD1) with the reference).

FIG. 14B illustrates an example of additional steps that may be applied in multi-plane memory arrays that include four or more planes (e.g., in addition to the steps in FIG. 14A). The steps include while applying the word line leak-detection conditions to the first selected block, applying the word line leak-detection conditions to a third selected block in a third plane to obtain a third word line leak-detection indicator 1450, while applying the word line leak-detection conditions to the first selected block, applying word line leak-detection conditions to a fourth selected block in a fourth plane 1452, subsequent to comparing the second word line leak-detection indicator with the one or more reference, comparing the third word line leak-detection indicator with the one or more reference 1454 and subsequent to comparing the third word line leak-detection indicator with the one or more reference, comparing the fourth word line leak-detection indicator with the one or more reference 1456.

An example of an apparatus includes control circuits to connect to planes of a nonvolatile memory array. The control circuits are configured to apply leak-detection voltages to selected blocks, each selected block located in a respective plane of the plurality of the nonvolatile memory array, obtain a leak-detection indicator for each selected block in parallel and compare each leak-detection indicator with a reference in series.

In one or more embodiments, the one or more control circuits are further configured to apply leak-detection conditions including word line voltages to each selected block in parallel.

In one or more embodiments, the one or more control circuits are further configured to obtain the leak-detection indicator as a respective leak-detection voltage for each selected block and to output the respective leak-detection voltages in parallel.

In one or more embodiments, the one or more control circuits include a multiplexer connected to receive the respective leak-detection voltages for the plurality of selected blocks in parallel and output a selected leak-detection voltage of the respective leak-detection voltages.

In one or more embodiments, the one or more control circuits further include an Analog-to-Digital Converter (ADC) connected to the multiplexer to receive the selected leak-detection voltage from the multiplexer and generate a multi-bit code from the selected leak-detection voltage.

In one or more embodiments, the one or more control circuits are configured to perform a binary search to obtain a digital code that corresponds to the multi-bit code.

In one or more embodiments, the one or more control circuits include, for each plane of the plurality of planes, a current mirror with a first branch connected to a respective selected block and current control circuit and a second branch connected to an output node that provides the leak-detection indicator.

In one or more embodiments, the plurality of planes comprises four planes, the one or more control circuits include a leak-detection indicator circuit for each plane, the leak-detection indicator circuits are connected to a multiplexer and analysis circuit to enable analysis of each leak-detection indicator in series.

In one or more embodiments, the one or more control circuits are located on a control die that is configured to be bonded to a memory die that includes the nonvolatile memory array.

An example of a method includes applying word line leak-detection conditions to a first selected block in a first plane to obtain a first word line leak-detection indicator; while applying the word line leak-detection conditions to the first selected block, applying word line leak-detection conditions to a second selected block in a second plane to obtain a second word line leak-detection indicator; comparing the first word line leak-detection indicator with one or more reference; and subsequently comparing the second word line leak-detection indicator with the one or more reference.

In one or more embodiments, the method further includes while applying the word line leak-detection conditions to the first selected block, applying the word line leak-detection conditions to a third selected block in a third plane to obtain a third word line leak-detection indicator; and while applying the word line leak-detection conditions to the first selected block, applying word line leak-detection conditions to a fourth selected block in a fourth plane to obtain a fourth word line leak-detection indicator.

In one or more embodiments, the method further includes subsequent to comparing the second word line leak-detection indicator with the one or more reference, comparing the third word line leak-detection indicator with the one or more reference; and subsequent to comparing the third word line leak-detection indicator with the one or more reference, comparing the fourth word line leak-detection indicator with the one or more reference.

In one or more embodiments, comparing the first word line leak-detection indicator with one or more reference includes comparing the first word line leak-detection indicator with a series of references selected from a range of references according to a binary search.

In one or more embodiments, the method further includes converting the first word line leak-detection indicator to a first digital code; and converting the second word line leak-detection indicator to a second digital code.

In one or more embodiments, converting the first and second word line leak-detection indicators to the first and second digital codes includes performing a binary search.

In one or more embodiments, comparing the first and second word line leak-detection indicators with the one or more reference includes comparing the first and second digital codes with a digital reference.

An example of a data storage system includes a plurality of nonvolatile memory cells arranged in a plurality of planes; and means for applying leak-detection voltages to selected blocks, each selected block located in a respective plane of the plurality of planes to obtain a leak-detection indicator for each selected block in parallel and comparing each leak-detection indicator with one or more reference in series.

In one or more embodiments, the plurality of nonvolatile memory cells are formed on a memory die and the means for applying and comparing is located on a control die that is bonded to the memory die to form an integrated memory assembly.

In one or more embodiments, the plurality of nonvolatile memory cells are arranged in NAND strings that are connected to word lines and the leak-detection voltages are applied to word lines to detect word line leakage.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of planes of a nonvolatile memory array, the one or more control circuits are configured to:
apply leak-detection voltages to a plurality of selected blocks, each selected block located in a respective plane of the plurality of planes, obtain a leak-detection indicator for each selected block in parallel and compare each leak-detection indicator with a reference in series.

2. The apparatus of claim 1, wherein the one or more control circuits are further configured to apply leak-detection conditions including word line voltages to each selected block in parallel.

3. The apparatus of claim 2, wherein the one or more control circuits are further configured to obtain the leak-detection indicator as a respective leak-detection voltage for each selected block and to output the respective leak-detection voltages in parallel.

4. The apparatus of claim 3, wherein the one or more control circuits include a multiplexer connected to receive the respective leak-detection voltages for the plurality of selected blocks in parallel and output a selected leak-detection voltage of the respective leak-detection voltages.

5. The apparatus of claim 4, wherein the one or more control circuits further include an Analog-to-Digital Converter (ADC) connected to the multiplexer to receive the selected leak-detection voltage from the multiplexer and generate a multi-bit code from the selected leak-detection voltage.

6. The apparatus of claim 5, wherein the one or more control circuits are configured to perform a binary search to obtain a digital code that corresponds to the multi-bit code.

7. The apparatus of claim 1, wherein the one or more control circuits include, for each plane of the plurality of planes, a current mirror with a first branch connected to a respective selected block and current control circuit and a second branch connected to an output node that provides the leak-detection indicator.

8. The apparatus of claim 1, wherein the plurality of planes comprises four planes, the one or more control circuits include a leak-detection indicator circuit for each plane, the leak-detection indicator circuits are connected to a multiplexer and analysis circuit to enable analysis of each leak-detection indicator in series.

9. The apparatus of claim 1, wherein the one or more control circuits are located on a control die that is configured to be bonded to a memory die that includes the nonvolatile memory array.

10. The apparatus of claim 1, wherein the nonvolatile memory array is a NAND memory.

11. A method comprising:
applying word line leak-detection conditions to a first selected block in a first plane to obtain a first word line leak-detection indicator;
while applying the word line leak-detection conditions to the first selected block, applying word line leak-detection conditions to a second selected block in a second plane to obtain a second word line leak-detection indicator;
comparing the first word line leak-detection indicator with one or more reference; and
subsequently comparing the second word line leak-detection indicator with the one or more reference.

12. The method of claim 11, further comprising:
while applying the word line leak-detection conditions to the first selected block, applying the word line leak-detection conditions to a third selected block in a third plane to obtain a third word line leak-detection indicator; and
while applying the word line leak-detection conditions to the first selected block, applying word line leak-detection conditions to a fourth selected block in a fourth plane to obtain a fourth word line leak-detection indicator.

13. The method of claim 12, further comprising:
subsequent to comparing the second word line leak-detection indicator with the one or more reference, comparing the third word line leak-detection indicator with the one or more reference; and
subsequent to comparing the third word line leak-detection indicator with the one or more reference, comparing the fourth word line leak-detection indicator with the one or more reference.

14. The method of claim 11, wherein comparing the first word line leak-detection indicator with one or more reference includes comparing the first word line leak-detection indicator with a series of references selected from a range of references according to a binary search.

15. The method of claim 14, further comprising:
converting the first word line leak-detection indicator to a first digital code; and
converting the second word line leak-detection indicator to a second digital code.

16. The method of claim 15, wherein converting the first and second word line leak-detection indicators to the first and second digital codes includes performing a binary search.

17. The method of claim 16, wherein comparing the first and second word line leak-detection indicators with the one or more reference includes comparing the first and second digital codes with a digital reference.

18. A data storage system comprising:
a plurality of nonvolatile memory cells arranged in a plurality of planes; and
means for applying leak-detection voltages to selected blocks, each selected block located in a respective plane of the plurality of planes to obtain a leak-detection indicator for each selected block in parallel and comparing each leak-detection indicator with one or more reference in series.

19. The data storage system of claim 18, wherein the plurality of nonvolatile memory cells are formed on a memory die and the means for applying and comparing is located on a control die that is bonded to the memory die to form an integrated memory assembly.

20. The data storage system of claim 18, wherein the plurality of nonvolatile memory cells are arranged in NAND strings that are connected to word lines and the leak-detection voltages are applied to word lines to detect word line leakage.
